(19) United States
(12) Patent Application Publication
(10) Pub. No.: US 2010/0193896 A1
(43) Pub. Date: Aug. 5, 2010

(54) METHOD FOR NITRIDATION OF SHALLOW TRENCH ISOLATION STRUCTURE TO PREVENT OXYGEN ABSORPTION

(76) Inventors: Kisik Choi, Hopewell Junction, NY (US); Changhwan Choi, Yorktown Heights, NY (US); Vijay Narayanan, New York, NY (US)

Correspondence Address: WILLIAMS, MORGAN & AMERSON, 10333 RICHMOND, SUITE 1100, HOUSTON, TX, 77042, US

(21) Appl. No.: 12/363,822

(22) Filed: Feb. 2, 2009

(51) Int. Cl. H01L 29/06; H01L 21/762

(52) U.S. Cl. 257/506; 438/424; 438/423; 257/E21.546; 257/E29.02

(57) ABSTRACT

A method for forming an isolation structure includes forming a trench in a semiconductor layer. At least a portion of the trench is filled with a dielectric material including oxygen. A region comprising nitrogen is formed in at least an upper portion of the dielectric material.

### CROSS-REFERENCE TO RELATED APPLICATIONS

Not applicable.

### BACKGROUND

The disclosed subject matter relates generally to semiconductor device manufacturing and, more particularly, to a method for nitridation of shallow trench isolation structure to prevent oxygen absorption.

Modern integrated circuits include a large number of circuit elements, such as resistors, capacitors, transistors and the like. Typically, these circuit elements are formed on and in a semiconductor layer, such as a silicon layer, and it is usually necessary to substantially electrically insulate adjacent semiconductor regions from each other. A representative example in this respect is a field effect transistor, the active area (i.e., the highly doped drain and source regions with an inversely lightly doped channel region disposed therebetween) of which is defined by an isolation structure formed in the semiconductor material.

Since critical feature sizes of the circuit elements, such as the gate length of field effect transistors, are steadily decreasing, the area enclosed by the isolation structures, as well as the isolation structures themselves, are also reduced in size. Among the various techniques for forming the isolation structures, a commonly used technique is the shallow trench isolation (STI) technique.

According to the STI technique, regions and/or individual circuit elements are insulated from each other by shallow trenches etched into the semiconductor material in which the circuit elements are to be formed (i.e., a semiconductor substrate when bulk semiconductor devices are considered or a semiconductor layer formed on an insulating substrate as in the case of silicon-on-insulator (SOI) substrates). The trenches are subsequently filled with a dielectric material, such as an oxide, to provide the required electrical insulation of adjacent regions and/or circuit elements.

It has been determined that oxygen atoms originating from STI structures can diffuse through the high-k materials or metal lines disposed over the STI structures and reach the active areas. These excess oxygen atoms can induce threshold voltage changes and, in some cases, can result in bottom interfacial layer re-growth. These negative effects tend to increase in severity as the width of the devices decreases at a given length and overlap of high-k/metal line over STI.

This section of this document is intended to introduce various aspects of art that may be related to various aspects of the disclosed subject matter described and/or claimed below. This section provides background information to facilitate a better understanding of the various aspects of the disclosed subject matter. It should be understood that the statements in this section of this document are to be read in this light, and not as admissions of prior art. The disclosed subject matter is directed to overcoming, or at least reducing the effects of, one or more of the problems set forth above.

### BRIEF SUMMARY

The following presents a simplified summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

One aspect of the disclosed subject matter is seen in a method for forming an isolation structure. The method includes forming a trench in a semiconductor layer. At least a portion of the trench is filled with a dielectric material including oxygen. A region comprising nitrogen is formed in at least an upper portion of the dielectric material.

Another aspect of the disclosed subject matter is seen in a semiconductor device including a semiconductor layer, a dielectric material including oxygen disposed in a trench defined in the semiconductor layer, and a region including nitrogen disposed in at least an upper portion of the dielectric material.

### BRIEF DESCRIPTION OF THE SEVERAL VIEWS OF THE DRAWINGS

The disclosed subject matter will hereafter be described with reference to the accompanying drawings, wherein like reference numerals denote like elements, and:

FIG. 1 is a cross-section view of a semiconductor device shallow trench isolation (STI) structure with a nitrogen-containing portion;

FIGS. 2-4 are cross-section views illustrating a method for forming the STI structure of FIG. 1 in accordance with one embodiment of the present subject matter;

FIGS. 4-6 are cross-section views illustrating a method for forming the STI structure of FIG. 1 in accordance with another embodiment of the present subject matter; and

FIG. 7 is a cross-section view of the STI structure of FIG. 1 with an overlying dielectric material.

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the spirit and scope of the disclosed subject matter as defined by the appended claims.

### DETAILED DESCRIPTION

One or more specific embodiments of the disclosed subject matter will be described below. It is specifically intended that the disclosed subject matter not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the disclosed subject matter unless explicitly indicated as being “critical” or “essential.”

The disclosed subject matter will now be described with reference to the attached figures. Various structures, systems and devices are schematically depicted in the drawings for purposes of explanation only and so as to not obscure the disclosed subject matter with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

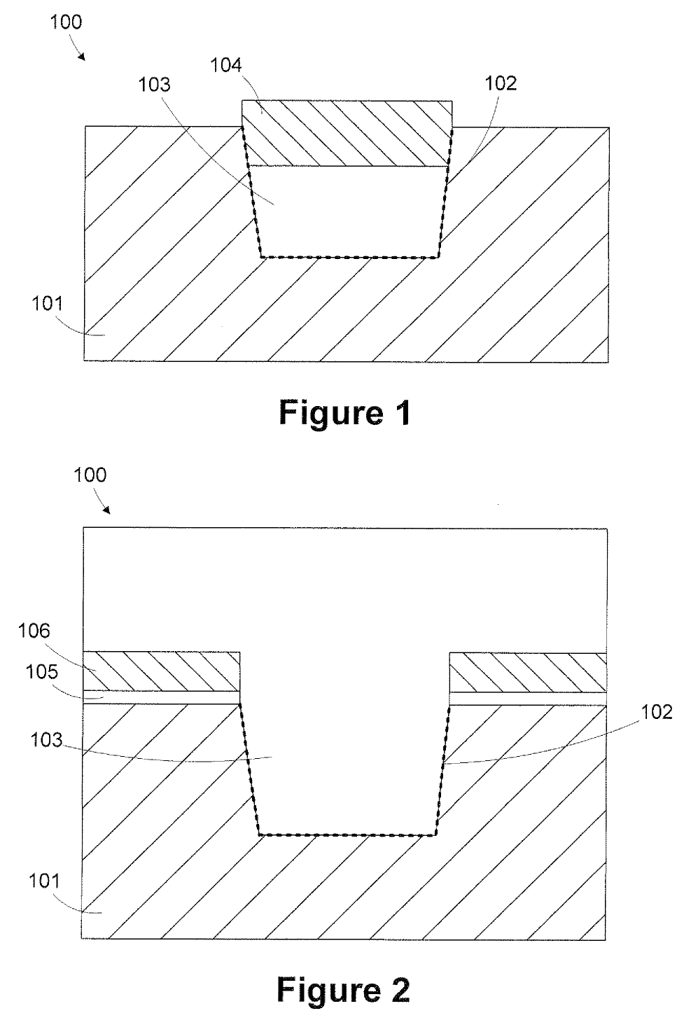

Referring now to the drawings wherein like reference numbers correspond to similar components throughout the several views and, specifically, referring to FIGS. 1-6, the disclosed subject matter shall be described in the context of a shallow trench isolation (STI) structure 100. The STI structure 100 is formed in a semiconductor layer 101, which may be an active layer or a semiconductor substrate, such as a silicon substrate, in and on which, circuit elements, such as field effect transistors and the like, are to be formed. A trench 102 (designated by dashed lines) formed in the semiconductor layer 101 is filled with a silicon dioxide material 103. The trench 104 may have tapered sidewalls, as illustrated in FIG. 1, or, alternatively, the sidewalls may be substantially perpendicular. The STI structure 100 includes a nitrogen-containing portion 104 disposed at in least an upper portion of the silicon dioxide material 103. Techniques for forming the nitrogen-containing portion 104 are described in greater detail below. In general, the nitrogen-containing portion 104 blocks diffusion of oxygen from the silicon dioxide material 103 through subsequently formed dielectric layers and/or metal lines to active regions of a semiconductor device formed in and/or above the semiconductor layer 101. Although the nitrogen-containing portion 104 is shown as partially encompassing the silicon dioxide material 103, it is contemplated that the nitrogen-containing portion 104 may completely encompass the silicon dioxide material 103.

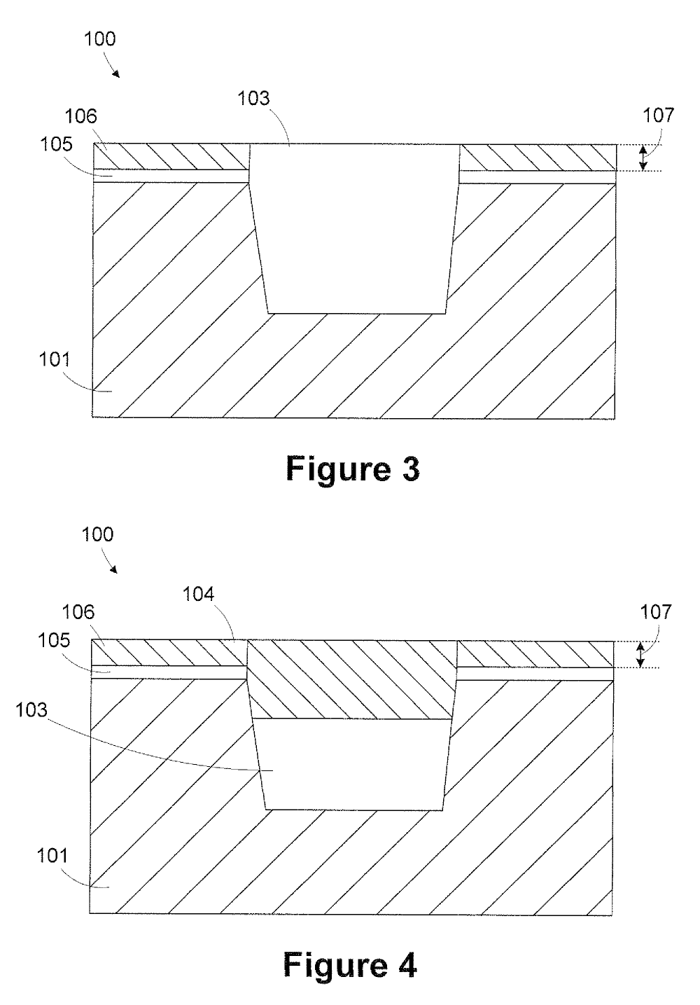

FIG. 2 illustrates a portion of a process flow for forming the STI structure 100 of FIG. 1. A pad oxide layer 105 (e.g., silicon dioxide) is formed on the semiconductor layer 101 followed by a pad nitride layer 106 (e.g., silicon nitride). Generally, the pad nitride layer 106 is used as a hard mask layer and the pad oxide layer 105 is used as an etch stop layer for subsequent removal of the pad nitride layer 106. Typically, the pad oxide layer 105 may be formed by thermally oxidizing the semiconductor layer 101 and, subsequently, the pad nitride layer 106 may be deposited by, for example, chemical vapor deposition (CVD), such as low pressure CVD (LPCVD). A layer of photoresist (not shown) may be applied and patterned by photolithography and etch techniques to expose the semiconductor layer 101 through the pad oxide layer 105 and the pad nitride layer 106 and pattern the trench 102 in the pad nitride layer 106, the pad oxide layer 105, and partially in the semiconductor layer 101. An anisotropic etch process for etching the pad nitride layer 106 may be designed to generate a tapered sidewall portion that may promote the fill capability of a subsequent deposition step. Sub-atmospheric CVD deposition techniques or high density plasma-enhanced CVD deposition techniques may be used for filling the trench 102 with the silicon dioxide material 103.

In FIG. 3, a planarizing process, such as chemical mechanical planarization (CMP) is employed to remove any portions of the silicon dioxide material 103 extending beyond the trench 102 and to provide a controlled reduction in a thickness 107 of the pad nitride layer 106. Controlling the remaining thickness 107 also controls the step height of the silicon dioxide material 103.

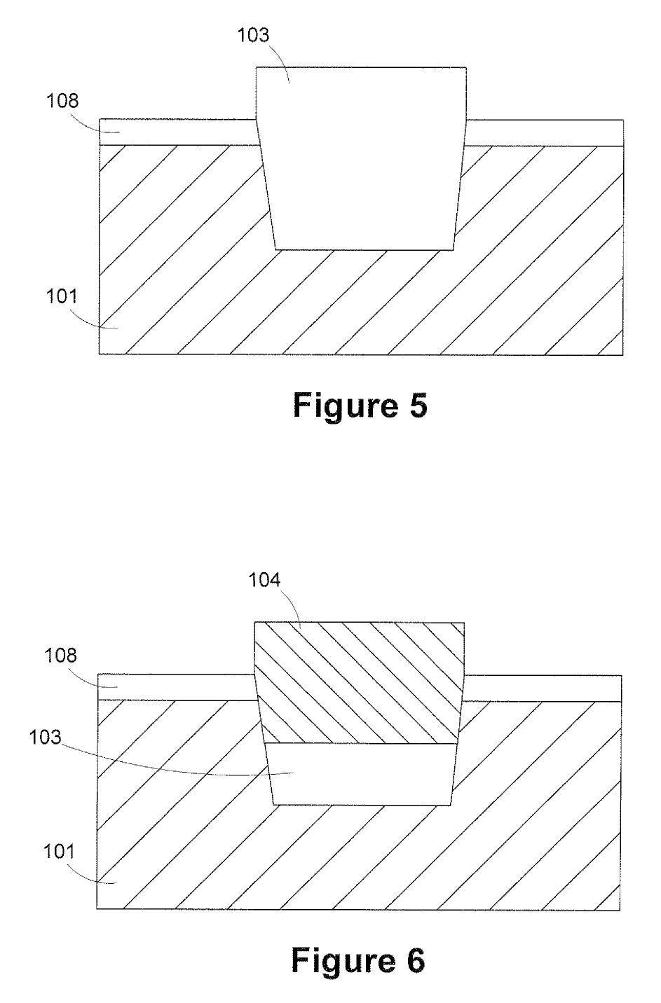

Following the planarization, a nitridation process is performed to create the nitrogen-containing portion 104, as shown in FIG. 4. In general, the nitridation process introduces atomic nitrogen into the silicon dioxide material 103. Some of the atomic nitrogen may react with the silicon dioxide to form SiON. Various techniques, such as diffusion or implantation may be used to form the nitrogen-containing portion 104. For example, a decoupled plasma nitridation (DPN) may be performed using a temperature of approximately 500° C., a pressure of approximately 5-100 mT, a nitrogen flow rate of approximately 100-1000 sccm, and a plasma power of approximately 100-2000 W. In another example, a slot plane antenna (SPA) nitridation may be performed using a temperature of approximately 100-500° C., a pressure of approximately 10-100 mT, a nitrogen flow rate of approximately 100-1000 sccm, and a power of approximately 100-2000 W. In yet another example a rapid thermal anneal in the presence of NH₃ may be performed at a temperature of approximately 500-1000° C., a pressure of approximately 10-700 Torr, an ammonia flow rate of approximately 1-10 lpm, and a process time of approximately 1-10 minutes. As an alternative to diffusion processes, nitrogen may be implanted using an implant energy of approximately 1-10 keV and a dose of approximately 1×10¹⁵-1×10²⁰ cm⁻³.

The pad nitride layer 106 and pad oxide layer 105 are removed following the nitridation, resulting in the STI structure 100 shown in FIG. 1. Typically, these layers may be removed by etch processes for removing nitride and oxide that are well known in the art, such as H₃PO₄ or other nitride removing chemicals such as tetramethyl ammonium hydroxide (TMAH) for removing the nitride and diluted hydrofluoric (DHF) acid for removing the oxide. During this removal a portion of the nitrogen-containing portion 104 may also be removed. The final step height of the STI structure 100 is essentially controlled by the amount of overpolish and the resulting reduction in thickness 107 of the pad nitride layer 106. The degree of overpolish may vary depending on the particular device design and the associated step height margin.

FIG. 5 illustrates a portion of an alternative process flow for forming the STI structure 100 of FIG. 1. As shown in FIG. 4, the pad oxide layer and pad nitride layer used for defining the trench 102 and the silicon dioxide material 103 are removed. A sacrificial oxide layer 108 (e.g., silicon dioxide) is formed on the semiconductor layer 101, (e.g., by a thermal oxidation process or a deposition process).

As shown in FIG. 6, a nitridation process, such as those illustrated above, is performed to create the nitrogen-containing portion 104. The thickness of the sacrificial oxide layer 108 is less than the previous combined thickness of the previously removed pad nitride and oxide layers, thereby allowing a deeper penetration depth for the nitrogen ions introduced into the silicon dioxide material 103. Also, the density of the sacrificial oxide layer 108 may be controlled to provide increased resistance to nitrogen penetration to prevent nitrogen absorption in the semiconductor layer 101. Following the nitridation, the sacrificial oxide layer 108 may be removed (e.g., using DHF), resulting in the STI structure 100 shown in FIG. 1.

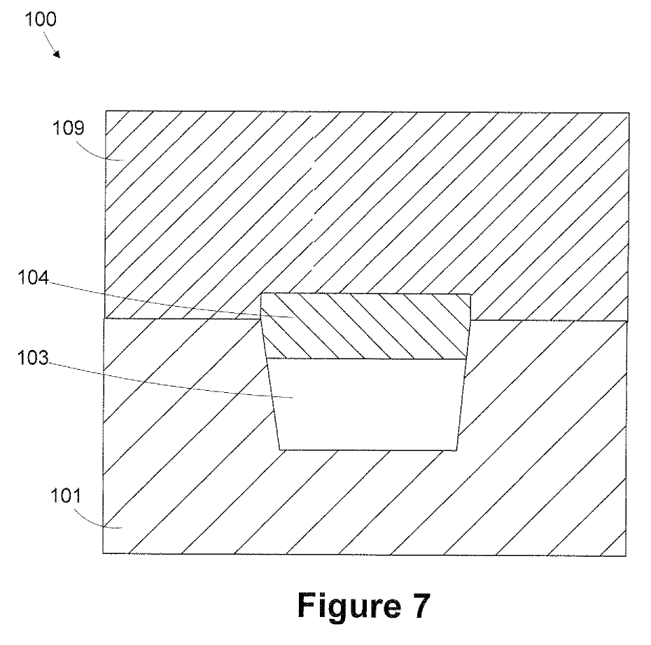

After completion of the STI structure 100 of FIG. 1, various other structures may be formed in and above the substrate, including transistors, metallization layers, etc. For example, as shown in FIG. 7, a high-k dielectric layer 109, such as HfO₂, HfSiOₓN_{y}, for example, may be formed above the STI structure 100. The nitrogen-containing portion 104 inhibits the absorption of oxygen in the material of the high-k dielectric layer 109 to mitigate the effects of oxygen migration toward adjacent and overlying active features. Inhibiting the movement of oxygen reduces the likelihood of threshold voltage changes or bottom interfacial layer re-growth occurring.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosed subject matter. Accordingly, the protection sought herein is as set forth in the claims below.

We claim:

1. A method for forming an isolation structure, comprising:
forming a trench in a semiconductor layer;
filling at least a portion of the trench with a dielectric material comprising oxygen; and
forming a region comprising nitrogen in at least an upper portion of the dielectric material.

2. The method of claim 1, wherein filling the trench with the dielectric material comprises filling the trench with silicon dioxide.

3. The method of claim 1, wherein forming the region comprising nitrogen comprises diffusing nitrogen into the dielectric material.

4. The method of claim 3, wherein diffusing the nitrogen comprises performing a decoupled plasma nitridation.

5. The method of claim 3, wherein diffusing the nitrogen comprises performing a slot plane antenna nitridation.

6. The method of claim 3, wherein diffusing the nitrogen comprises performing a rapid thermal anneal in the presence of nitrogen.

7. The method of claim 1, wherein forming the region comprising nitrogen comprises implanting nitrogen into the dielectric material.

8. The method of claim 1, wherein the region comprising nitrogen comprises atomic nitrogen.

9. The method of claim 1, wherein the region comprising nitrogen comprises SiON.

10. The method of claim 1, further comprising:
forming at least one hard mask layer over the semiconductor layer prior to forming the trench;
patterning the hard mask layer to define an opening exposing the semiconductor layer;
etching the trench through the opening;
filling the trench with the dielectric material; and
removing at least a portion of the dielectric material disposed above the hard mask layer.

11. The method of claim 10, further comprising overpolishing the hard mask layer after removing the dielectric material disposed above the hard mask layer to provide a controlled reduction of a thickness of the hard mask layer to achieve a target remaining thickness of the hard mask layer.

12. The method of claim 11, further comprising:
forming the region comprising nitrogen; and
removing the hard mask layer with the reduced thickness.

13. The method of claim 10, further comprising:
removing the hard mask layer;
forming a sacrificial oxide layer above the semiconductor layer;
forming the region comprising nitrogen after forming the sacrificial oxide layer; and
removing the sacrificial oxide layer.

14. The method of claim 1, further comprising forming a high-k dielectric layer above the semiconductor layer and the region comprising nitrogen.

15. The method of claim 1, wherein forming the region comprising nitrogen comprises forming the region to fully encompass the dielectric material.

16. A method, comprising:
forming a trench in a semiconductor layer;
filling at least a portion of the trench with silicon dioxide; and
performing a nitridation process to form a region comprising nitrogen in at least an upper portion of the silicon dioxide.

17. The method of claim 16, further comprising forming a high-k dielectric layer above the semiconductor layer and the region comprising nitrogen.

18. The method of claim 16, wherein forming the region comprising nitrogen comprises diffusing nitrogen into the silicon dioxide.

19. The method of claim 16, wherein forming the region comprising nitrogen comprises implanting nitrogen into the silicon dioxide.

20. The method of claim 16, wherein forming the region comprising nitrogen comprises forming the region to fully encompass the dielectric material.

21. A semiconductor device, comprising:
a semiconductor layer;
a dielectric material comprising oxygen disposed in a trench defined in the semiconductor layer, and
a region comprising nitrogen disposed in at least an upper portion of the dielectric material.

22. The semiconductor device of claim 21, wherein the dielectric material comprises silicon dioxide.
